(19) United States
(12) Patent Application Publication
(10) Pub. No.: US 2025/0201733 A1
(43) Pub. Date: Jun. 19, 2025

(54) Semiconductor Device and Method of Forming Protective Layer on Substrate to Avoid Damage During Encapsulation

(71) Applicant: JCET STATS ChipPAC Korea Limited, Incheon (KR)

(72) Inventors: HyeonChul Lee, Seoul (KR); KyoungHee Park, Seoul (KR); KyungHwan Kim, Seoul (KR)

(73) Assignee: JCET STATS ChipPAC Korea Limited, Incheon (KR)

(21) Appl. No.: 18/545,467

(22) Filed: Dec. 19, 2023

(51) Int. Cl. H01L 23/00; H01L 21/48; H01L 21/56; H01L 23/498; H01L 23/552

(52) U.S. Cl. CPC H01L 23/562; H01L 21/4846; H01L 21/565; H01L 23/552; H01L 23/49827; H01L 24/16; H01L 2224/16227

(57) ABSTRACT

A semiconductor device has a substrate and a protective layer formed over a saw street of the substrate. The protective layer may extend over a width of the saw street. The protective layer may extend less than a width of the saw street or extend greater than a width of the saw street. An electrical component is disposed over a surface of the substrate. A connector is disposed over the surface of the substrate. An encapsulant is deposited over the electrical component using a chase mold with a lower housing and upper housing. The encapsulant should not migrate to the connector during encapsulation. High pressure is applied to an upper housing of the chase mold to prevent encapsulant migration to the connector. The protective layer protects the substrate from the high pressure during encapsulation. A shielding layer is formed over the encapsulant.

### FIELD OF THE INVENTION

The present invention relates in general to semiconductor devices and, more particularly, to a semiconductor device and method of forming a protective layer on a substrate to avoid damage during encapsulation.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system-in-package (SiP) module for higher density in a small space and extended electrical functionality. Within the SiP module, semiconductor die and IPDs are disposed on a first surface of a substrate for structural support and electrical interconnect. An encapsulant is deposited over the semiconductor die, IPDs, and substrate. An electrical connector is disposed on the first surface of the substrate for electrical communication between the electrical components and external devices.

An antenna can be disposed on a second surface of the substrate to provide wireless communication for the SiP module. With the addition of the antenna, the SiP constitutes an antenna-in-package (AiP). In any case, it is important that the encapsulant does not migrate from the electrical components to the connector. Any encapsulant reaching the connector can cause a defect in the SiP or AiP. A chase mold is utilized for encapsulation. The chase mold includes a lower housing and upper housing. The SiP or AiP is placed in the lower housing and then enclosed by the upper housing. A significant pressure is typically applied to the upper housing to prevent molding compound from creeping onto the connector. However, the high pressure on the upper housing needed to prevent undesired leakage of the encapsulant into the connector area can also crack or damage the substrate or SiP or AiP. It is desired to prevent migration of encapsulant into the connector area, without damaging the substrate or SiP or AiP, in order to reduce or minimize defects.

### BRIEF DESCRIPTION OF THE DRAWINGS

FIGS. 1a-1c illustrate a semiconductor wafer with a plurality of semiconductor die separated by a saw street;

FIGS. 2a-2n illustrate a process of forming an AiP substrate with a protective layer formed in the saw street to limit pressure on the substrate during encapsulation;

FIGS. 3a-3d illustrate further detail of the protective layer;

FIGS. 4a-4b illustrate further detail of the protective layer post encapsulation;

FIGS. 5a-5c illustrate the AiP substrate post encapsulation with a shielding layer;

FIGS. 6a-6b illustrate singulation of the AiP substrate;

FIGS. 7a-7b illustrate the AiP post singulation with the shielding layer; and

FIG. 8 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

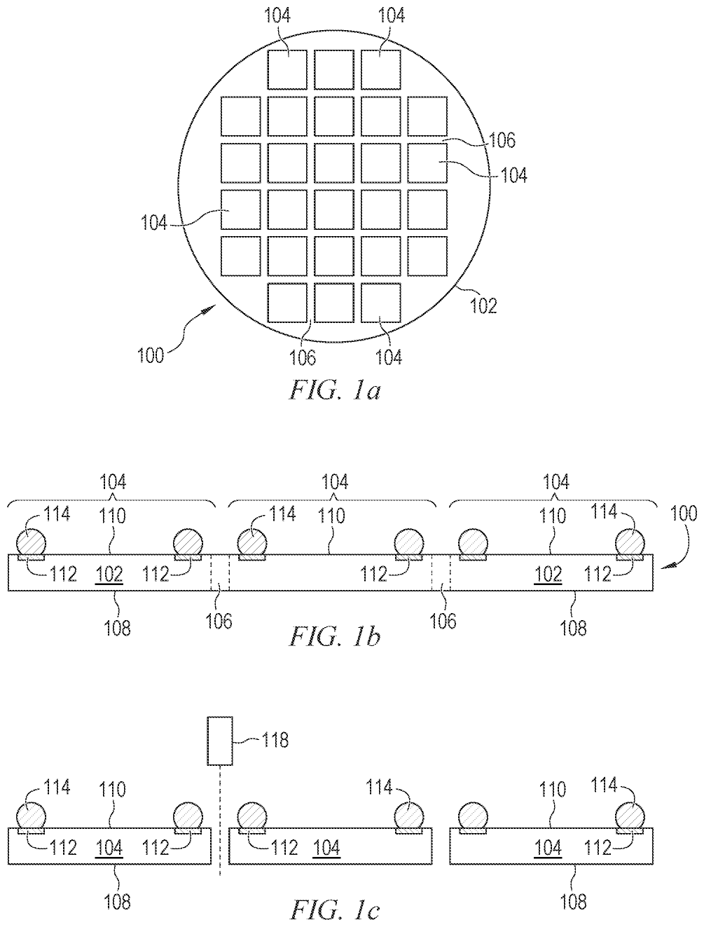

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Semiconductor die 104 can process RF signals transmitted and received through an antenna.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

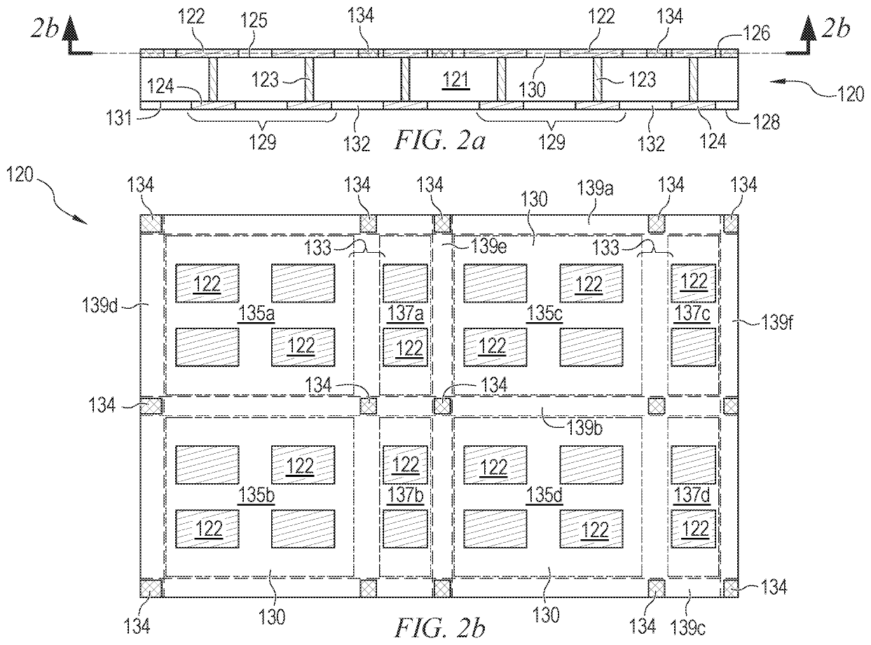

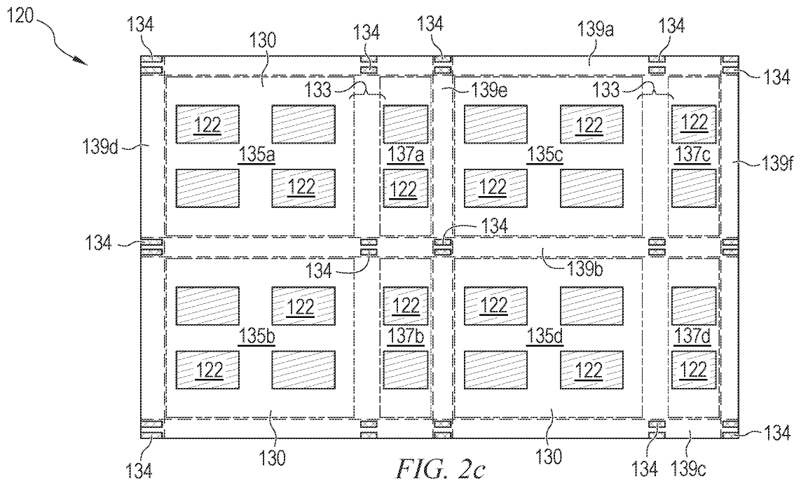

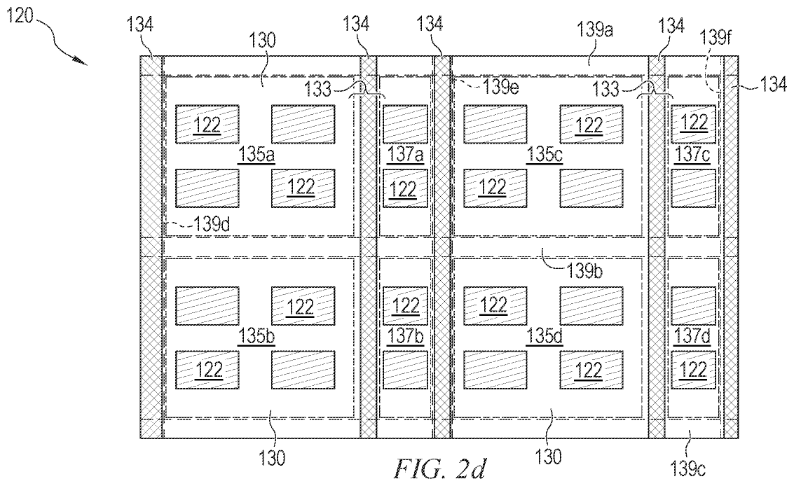

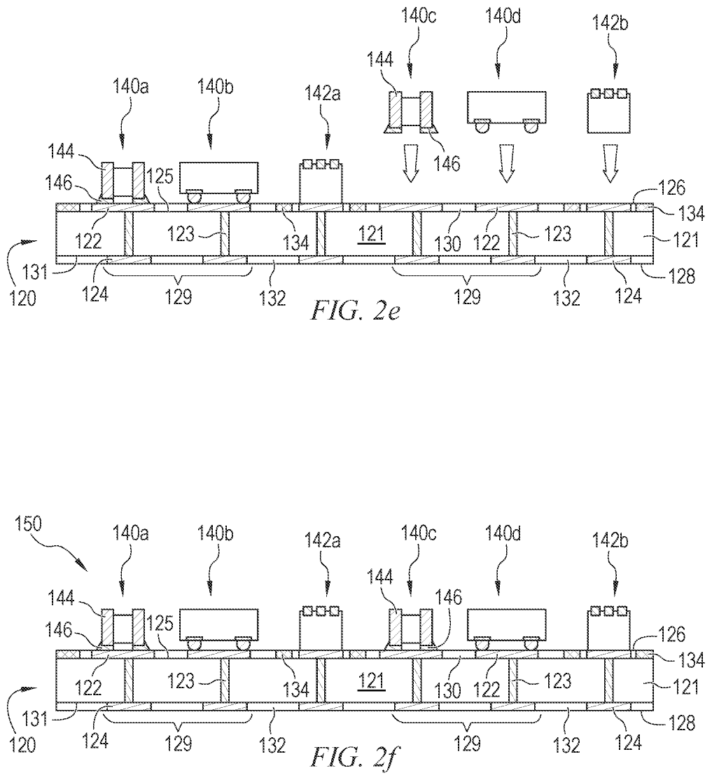

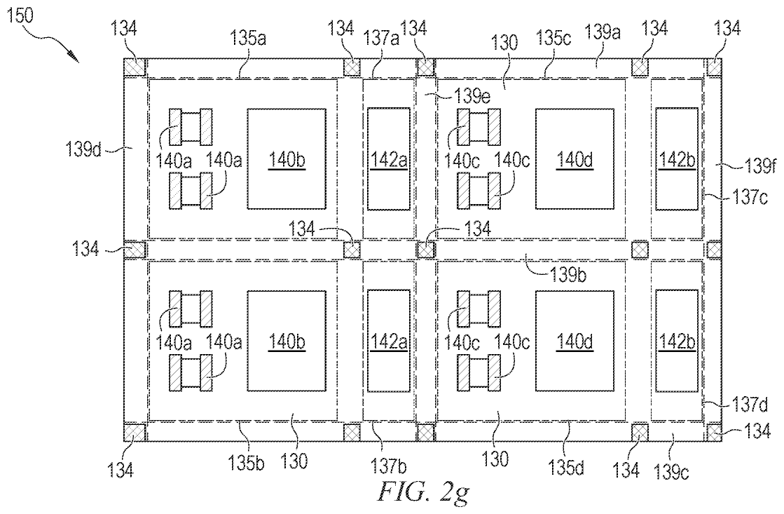

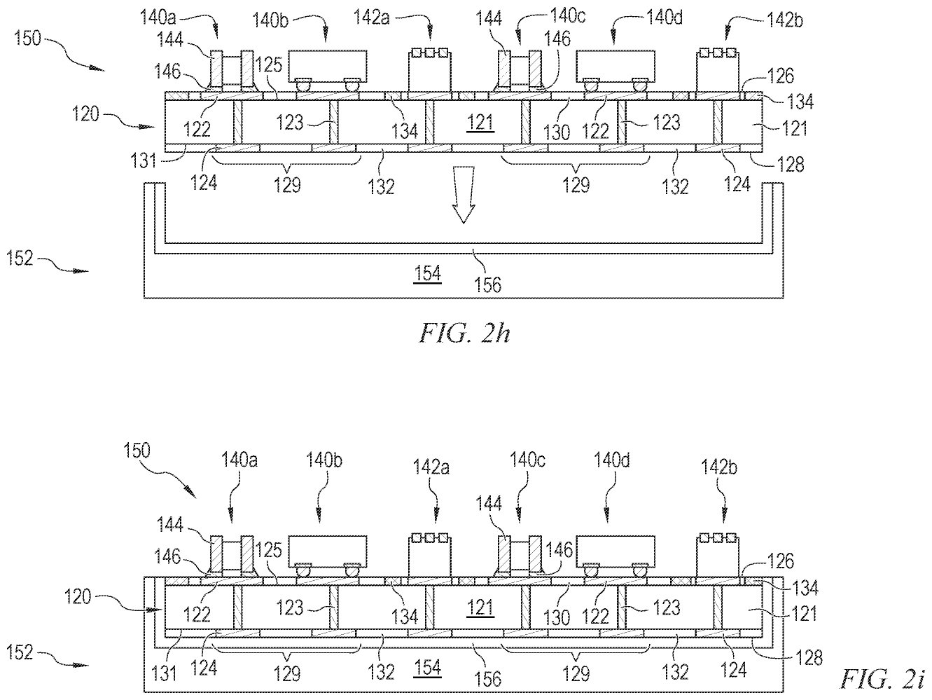

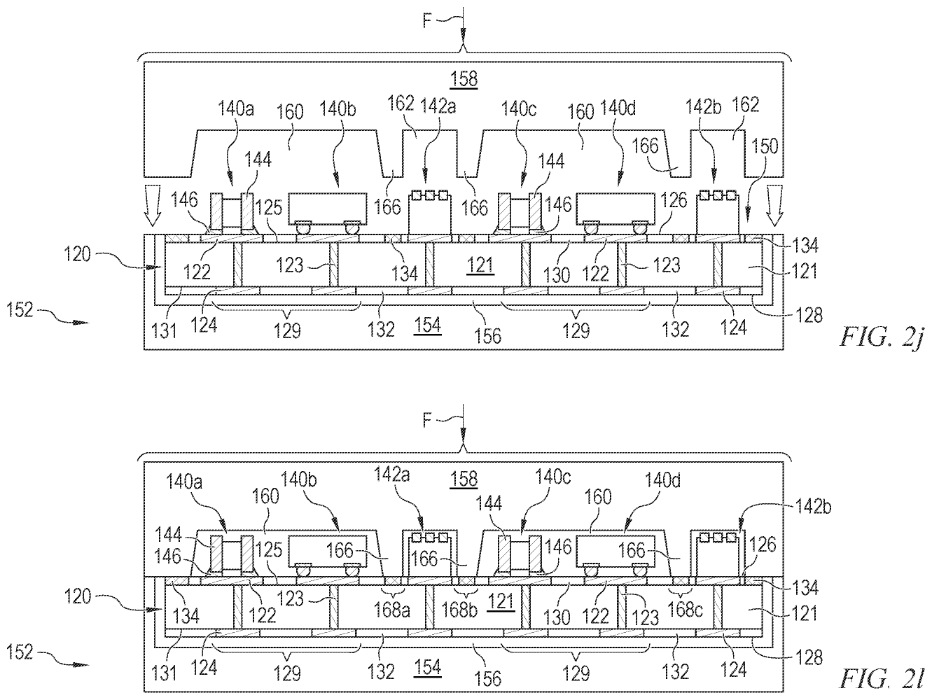

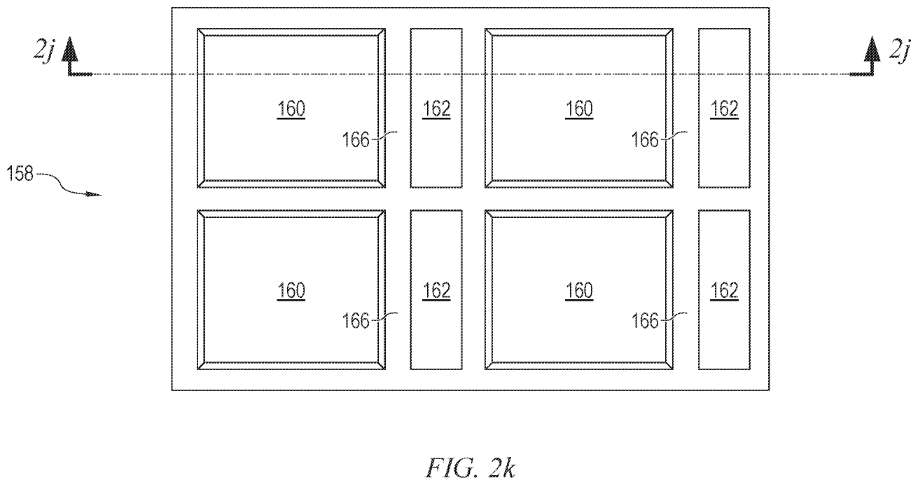

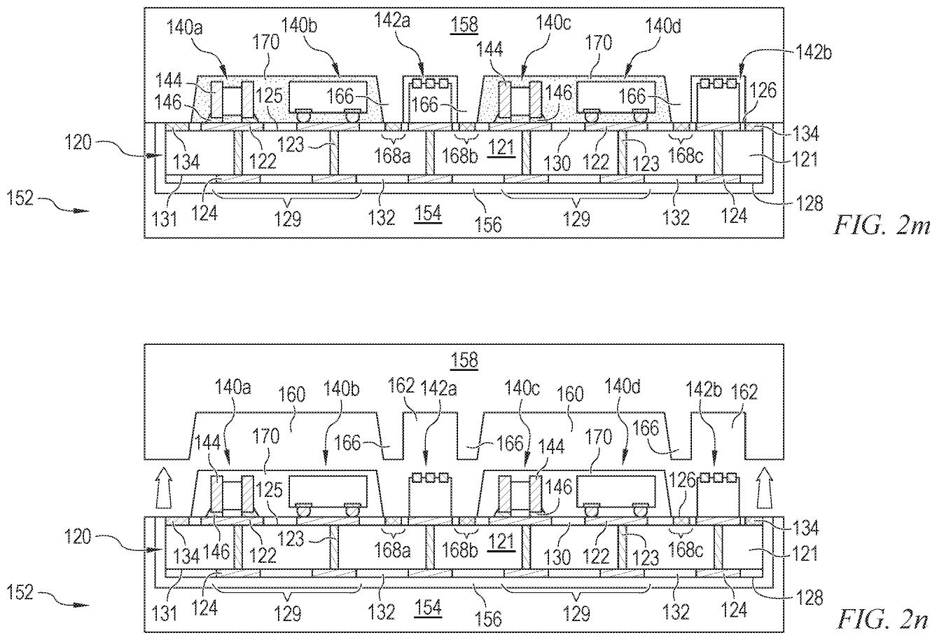

FIGS. 2a-2n illustrate a process of forming an AiP substrate with a protective layer formed in the saw street to limit pressure on the substrate during encapsulation. FIG. 2a shows a cross-sectional view of interconnect and antenna substrate 120 including core material 121, such as silicon, germanium, aluminum phosphide, aluminum arsenide, gallium arsenide, gallium nitride, indium phosphide, silicon carbide, or other bulk material for structural support. Alternatively, core material 121 can be a multi-layer flexible laminate, ceramic, copper clad laminate (CCL), glass, or epoxy molding compound. Core material 121 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Conductive vias 123 are formed through core material 121 by forming vias through the core material and filling the vias with conductive material.

An insulating layer 130 is formed over surface 125 of core material 121. Insulating layer 130 contains one or more layers of SiO2, Si3N4, SiON, Ta2O5, Al2O3, polyimide, BCB, PBO, and other material having similar insulating and structural properties. In one embodiment, insulating layer 130 is solder resist. Insulating layers 130 can be formed using PVD, CVD, printing, lamination, spin coating, spray coating, sintering or thermal oxidation. A portion of insulating layer 130 is removed by an etching or laser direct ablation (LDA) and one or more conductive layers 122 are formed over surface 125 of core material 121. Conductive layer 122 can be formed prior to insulating layer 130. Conductive layer 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal and vertical electrical interconnect across substrate 120. Portions of conductive layers 122 can be electrically common or electrically isolated depending on the design and function of semiconductor die 104 and other electrical components. Insulating layers 130 provide isolation between conductive layers 122. There can be multiple conductive layers like 122 separated by multiple insulating layers like 130.

An insulating layer 132 is formed over surface 131 of core material 121, opposite surface 125. Insulating layer 132 contains one or more layers of SiO2, Si3N4, SiON, Ta2O5, Al2O3, polyimide, BCB, PBO, and other material having similar insulating and structural properties. In one embodiment, insulating layer 132 is solder resist. Insulating layers 132 can be formed using PVD, CVD, printing, lamination, spin coating, spray coating, sintering or thermal oxidation. A portion of insulating layer 132 is removed by an etching or LDA and one or more conductive layers 124 are formed over surface 131 of core material 121. Conductive layer 124 can be formed prior to insulating layer 132. Conductive layer 124 can be one or more layers of Al, Cu, Sn, Ni, Au, Ag, or other suitable electrically conductive material. Conductive layers 124 can be formed using PVD, CVD, electrolytic plating, electroless plating process, or other suitable metal deposition process. In one embodiment, conductive layer 124 operates as antenna area 129 to transmit and receive RF signals for later-mounted electrical components. The electrical components will be electrically connected to antenna area 129 by way of the vertical and horizontal segments of conductive layers 122 and conductive vias 123. Portions of conductive layers 124 can be electrically common or electrically isolated depending on the design and function of semiconductor die 104 and other electrical components. Insulating layers 132 provide isolation between conductive layers 124. There can be multiple conductive layers like 124 separated by multiple insulating layers like 132. With antenna area 129, interconnect substate 120 becomes an AiP substrate.

FIG. 2b is a top view of substrate 120. Substrate 120 contains die or component mounting sites 135a, 135b, 135c, and 135d for later-mounted electrical components. Substrate 120 also contains connector mounting sites 137a, 137b, 137c, and 137d for later-mounted connectors. Note that area 133 separates die or component mounting sites 135a-135d from connector mounting sites 137a-137d, respectively. Area 133 provides a clamping area or line to avoid the situation or possibility of encapsulant, which will later cover the electrical components, from migrating onto and contaminating the connectors, further explanation infra. Saw streets 139a-139f separate die or component mounting sites 135a-135d and connector mounting sites 137a-137d, as shown.

A protective layer 134 is formed over insulating layer 130 and/or core substrate 121 using PVD, CVD, electrolytic plating, electroless plating process, or other suitable metal deposition process. In one embodiment, protective layer 134 is a conductive layer made with one or more layers of Al, Cu, Sn, Ni, Au, Ag, or other suitable electrically conductive material. Protective layer 134 spans a width of saw street 139a-139f to protect insulating layer 130 during a subsequent encapsulation process, as described infra.

FIG. 2c illustrates another embodiment of protective

layer 134 shown as narrow strips measuring less than a width of saw streets 139a-139f. FIG. 2d illustrates yet another embodiment of protective layer 134 shown to span a width and length of saw streets 139d-139f. Elements having a similar function are assigned the same reference number.

In FIG. 2e, a plurality of electrical components 140a-140d is disposed on surface 126 of interconnect substrate 120 to be electrically and mechanically connected to conductive layers 122. Electrical components 140a-140d are each positioned over substrate 120 using a pick and place operation. For example, electrical components 140a and 140c can be a discrete electrical device, or IPDs, such as a diode, transistor, resistor, capacitor, and inductor, with terminals 144 disposed on surface 126 of interconnect substrate 120 and electrically and mechanically connected to conductive layers 122. Electrical components 140b and 140d can be similar to semiconductor die 104 from FIG. 1c with active surface 110 and bumps 114 oriented toward surface 126 of substrate 120. Alternatively, electrical components 140a-140d can include other semiconductor die, semiconductor packages, surface mount devices, discrete electrical devices, or IPDs.

Electrical components 140a-140d are brought into contact with surface 126 of substrate 120. Bumps 114 are reflowed to mechanically and electrically connect electrical components 140b and 140d to conductive layer 122. Conductive paste 146 bonds electrical components 140a and 140c to conductive layer 122.

In a similar manner, a plurality of electrical connectors 142a-142b is disposed on surface 126 of interconnect substrate 120 to be electrically and mechanically connected to conductive layers 122. Connectors 142a-142b are each positioned over substrate 120 using a pick and place operation. Connectors 142a-142b are brought into contact with surface 126 of substrate 120 and mechanically and electrically connected to conductive layer 122, e.g., with conductive paste similar to 146 or bumps similar to 114.

FIG. 2f shows electrical components 140a-140d and connectors 142a-142b mechanically and electrically connected to conductive layer 122 of interconnect substrate 120, referenced hereinafter as assembly 150. FIG. 2g is a top view of assembly 150 with electrical components 140a-140d disposed in die and components mounting sites 135a-135d and connectors 142a-142b disposed in connector mounting sites 137a-137d. Assembly 150 further includes saw streets 139a-139f with protective layer 134 disposed in the saw streets.

In FIG. 2h, assembly 150 is disposed over chase mold 152, including lower chase mold housing 154 and assembly pocket 156. Assembly 150 is placed in assembly pocket 156 of lower chase mold housing 154, as shown in FIG. 21.

In FIG. 2j, upper chase mold housing 158 of chase mold 152 is disposed over assembly 150 and assembly pocket 156. Upper chase mold housing 158 includes cavities or pockets 160 intended to cover electrical components 140a-140d and cavities or pockets 162 intended to cover connector 142a-142b. Pockets 160 and 162 define sidewalls 166 of upper chase mold housing 158. FIG. 2k shows a bottom view of pockets 160 and 162 and sidewalls 166 of upper chase mold housing 158. Upper chase mold housing 158 is disposed over lower chase mold housing 154 with electrical components 140a-140d contained within pockets 160 and connectors 142a-142b contained within pockets 162, as shown in FIG. 21.

The purpose of chase mold 152 is to deposit encapsulant around electrical components 140a-140d, using a process known as finger molding. However, no encapsulant should reach connectors 142a-142b as that situation could contaminate the connectors and cause a defect in assembly 150. Accordingly, upper chase mold housing 158 makes a tight seal against lower chase mold housing 154 upon application of force F. The high pressure contact between upper chase mold housing 158 and lower chase mold housing 154 is to prevent encapsulant from creeping under and around sidewalls 166 into connector mounting sites 137a-137d and contaminating connectors 142a-142b. Yet, the high pressure contact between upper chase mold housing 158 and lower chase mold housing 154 in part contacts assembly 150, at least at contact points or areas 168a, 168b, and 168c. In particular, sidewalls 166 of upper chase mold housing 158 around pockets 160 and 162 apply significant pressure against insulating layer 130 and interconnect substrate 120 at least at contact points or areas 168a-168c. The pressure can crack insulating layer 130 and the crack can propagate to other areas of substrate 120.

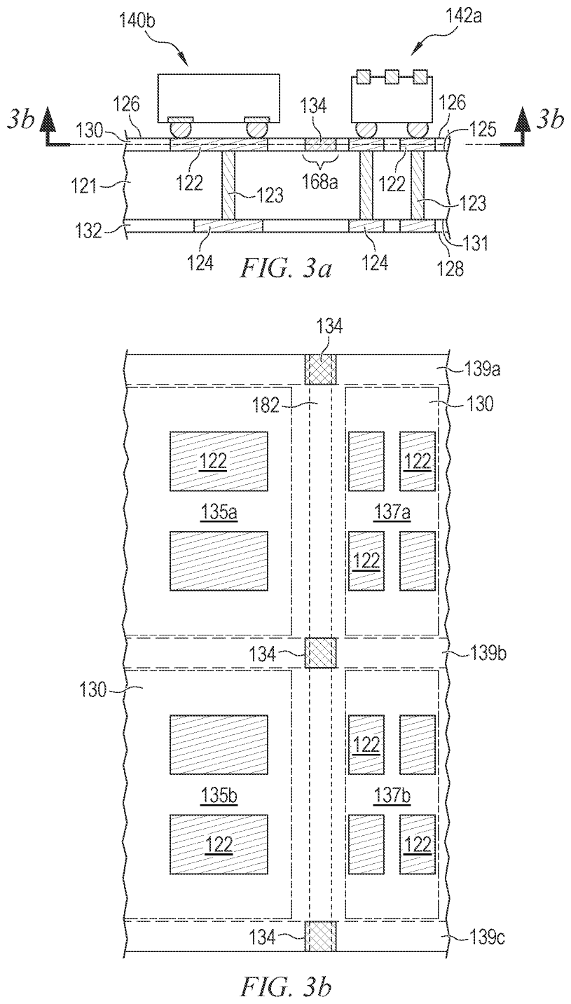

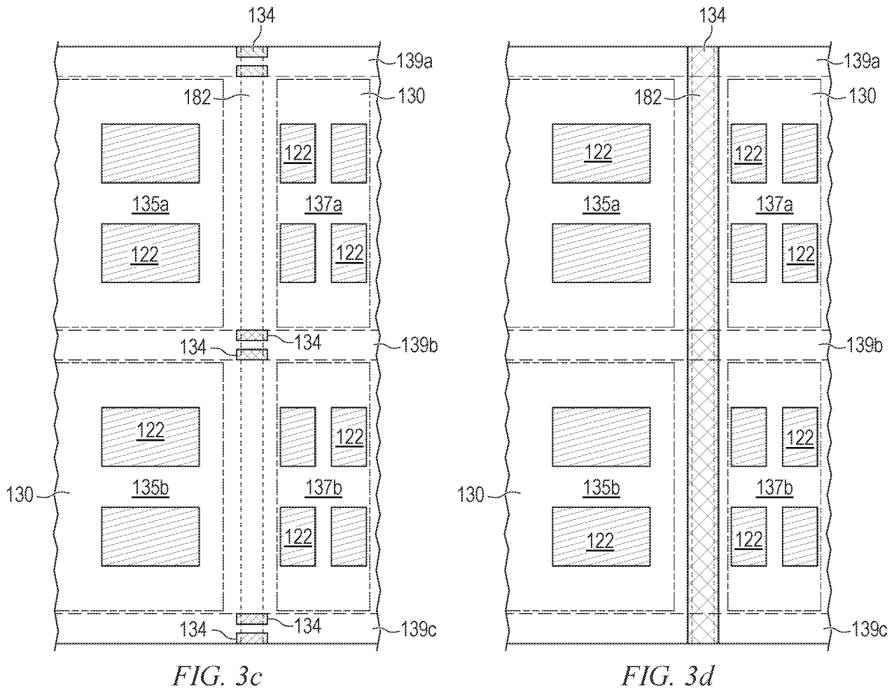

To avoid damaging interconnect substrate 120, i.e., cracking insulating layer 130 or any other portion of the substrate, protective layer 134 has been formed in saw streets 139a-139f. FIG. 3a shows further detail of a portion of assembly 150 with electrical component 140b disposed in die or component mounting site 135a and connector 142a disposed in connector mounting site 137a of interconnect substrate 120. Protective layer 134 is formed in insulating layer 130 along, for example, saw street 139a and 139b. In particular, protective layer 134 is formed in saw streets 139a-139f at locations and/or crossing points along clamping line 182 where sidewalls 166 will contact insulating layer 130 of substrate 120.

FIG. 3b is a top view of protective layer 134 formed in insulating layer 130 along saw streets 139a-139c. Clamping line 182 is the area of contact between sidewalls 166 of upper chase mold housing 158 and insulating layer 130 on interconnect substrate 120. Protective layer 134 in saw streets 139a-139f operate as support structures that can withstand the pressure from sidewalls 166 at contact points 168a-168c under force F, without damage to insulating layer 130 or any other portion of interconnect substrate 120. While sidewalls 166 of upper chase mold housing 158 do indeed contact insulating layer 130 to make a tight seal and prevent encapsulant 170 from creeping under sidewalls or around sidewalls 166 of upper chase mold housing 158 and onto connectors 142a, protective layer 134 limits the pressure on the insulating layer to avoid damage to insulating layer 130 and/or interconnect substrate 120.

FIG. 3c is another embodiment, similar to FIG. 3b, with protective layer 134 occupying less than a width of saw streets 139a-139c. Again, protective layer 134 limits the pressure on insulating layer 130 to avoid damage to insulating layer 130 and/or interconnect substrate 120.

FIG. 3d is another embodiment, similar to FIG. 3b, with protective layer 134 occupying the length of clamping line 182. Again, protective layer 134 limits the pressure on insulating layer 130 to avoid damage to insulating layer 130 and/or interconnect substrate 120.

Returning to FIG. 2m, an encapsulant or molding compound 170 is injected into pockets 160 and deposited over and around electrical components 140a-140d and substrate 120, up to saw streets 139a-139f, referred to as finger molding. Encapsulant 170 can be polymer composite material, such as epoxy resin with filler, epoxy acrylate with filler, or polymer with proper filler. Encapsulant 170 is non-conductive, provides structural support, and environmentally protects the semiconductor device from external elements and contaminants.

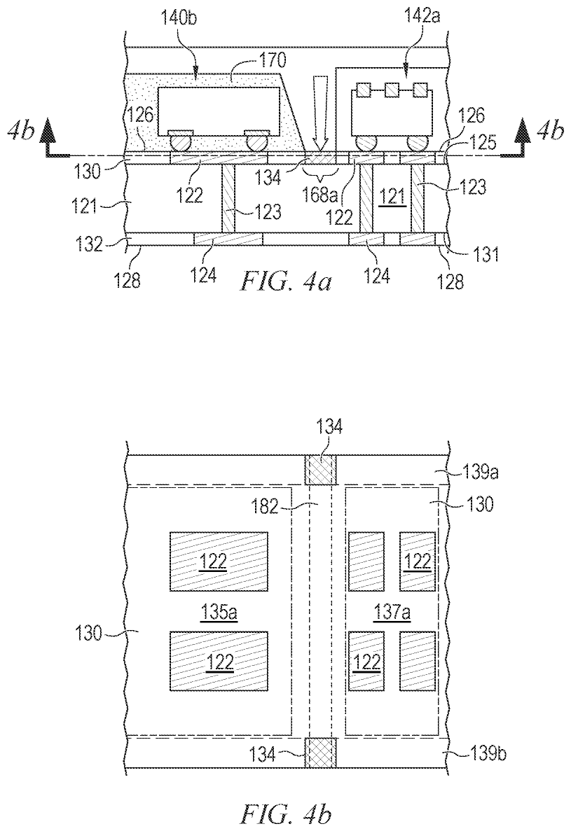

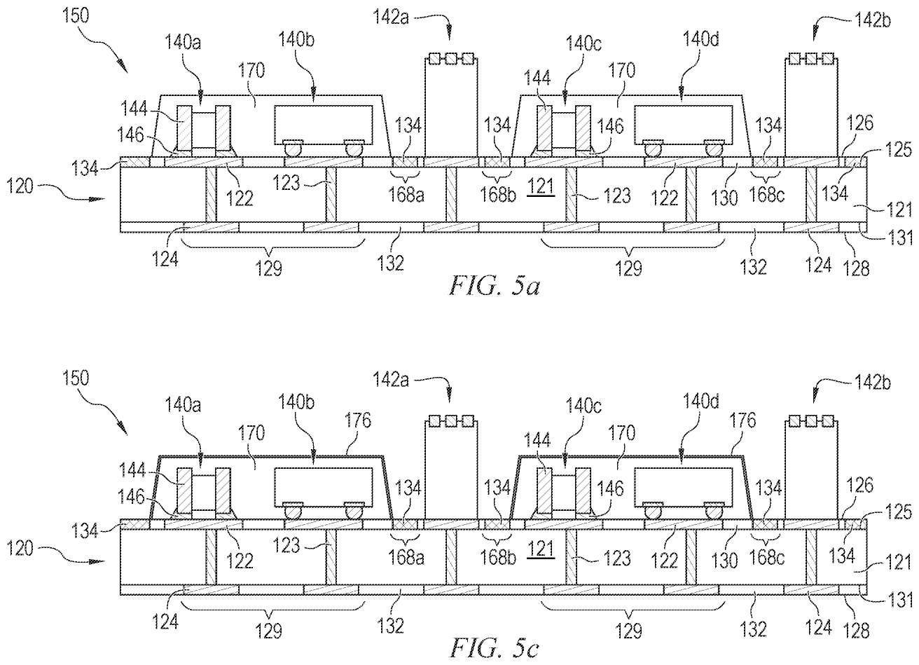

FIG. 4a shows further detail of a portion of assembly 150 with electrical component 140b disposed in die or component mounting site 135a and connector 142a disposed in connector mounting site 137a of interconnect substrate 120 and encapsulant 170 disposed around to finger mold the electrical components. Protective layer 134 is formed in insulating layer 130 along, for example, saw street 139b. FIG. 4b is a top view of protective layer 134 formed in insulating layer 130 along saw streets 139a-139c. Clamping line 182 is the area of contact between sidewalls 166 of upper chase mold housing 158 and insulating layer 130 on interconnect substrate 120. Protective layer 134 in saw streets 139a-139f operate as support structures that can withstand the pressure from sidewalls 166 at contact points 168a-168c under force F, without damage to insulating layer 130 or any other portion of interconnect substrate 120. While sidewalls 166 of upper chase mold housing 158 do indeed contact insulating layer 130 to make a tight seal and prevent the encapsulant from creeping under or around sidewalls 166 of upper chase mold housing 158 and onto connectors 142a, protective layer 134 limits the pressure on the insulating layer to avoid damage to insulating layer 130 and/or interconnect substrate 120.

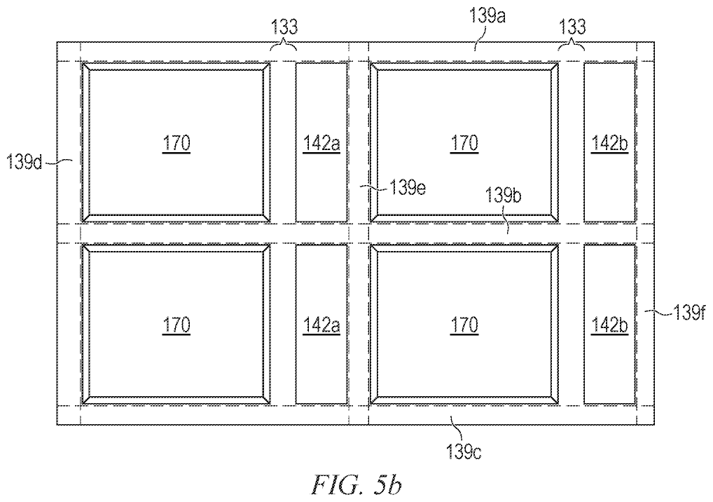

Returning to FIG. 2n, upper chase mold housing 158 is lifted off lower chase mold housing 154. FIG. 5a shows assembly 150 following removal from chase mold 152 with encapsulant 170 deposited around or finger molded to electrical components 140a-140d. FIG. 5b shows a top view of assembly 150 with encapsulant 170 deposited around or finger molded to electrical components 140a-140d. Encapsulant extends up to saw streets 139a-139f, but stops short of connectors 142a-142b due to tight sidewalls 166 and protective layer 134 in area 133 protecting substrate 120. There is no encapsulant on connectors 142a-142b. Substrate 120 remains undamaged from chase mold 152 by nature of protective layer 134 limiting the pressure on insulating layer 130 and/or substrate 120.

Electrical components 140a-140d may contain IPDs that are susceptible to or generate EMI, RFI, harmonic distortion, and inter-device interference. For example, the IPDs contained within electrical components 140a-140d provide the electrical characteristics needed for high-frequency applications, such as resonators, high-pass filters, low-pass filters, band-pass filters, symmetric Hi-Q resonant transformers, and tuning capacitors. In another embodiment, electrical components 140a-140d contain digital circuits switching at a high frequency, which could interfere with the operation of IPDs in the assembly.

To address EMI, RFI, harmonic distortion, and inter-device interference, electromagnetic shielding material 176 is applied over encapsulant 170, as shown in FIG. 5c. Electromagnetic shielding material 176 can be one or more layers of Al, Cu, Sn, Ni, Au, Ag, or other suitable conductive material. Alternatively, electromagnetic shielding material 176 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

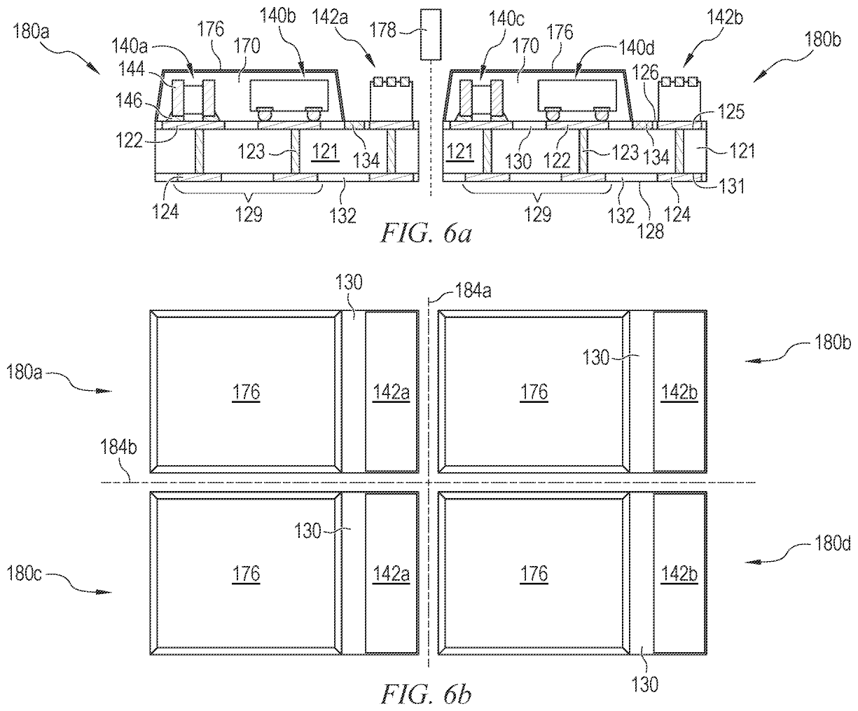

In FIG. 6a, assembly 150 is singulated through saw streets 139a-139f using a saw blade or laser cutting tool 178 into individual semiconductor packages, or in the case of conductive layer 124 operating as an antenna, then individual AiP 180a-180d. FIG. 6b shows a top view of the singulation along lines 184a and 184b. The singulation through saw streets 139a-139f leaves shielding material 176 over encapsulant 170 at the edge of AiP 180a-180d. Protective layer 134 is typically, although not necessarily, removed during singulation.

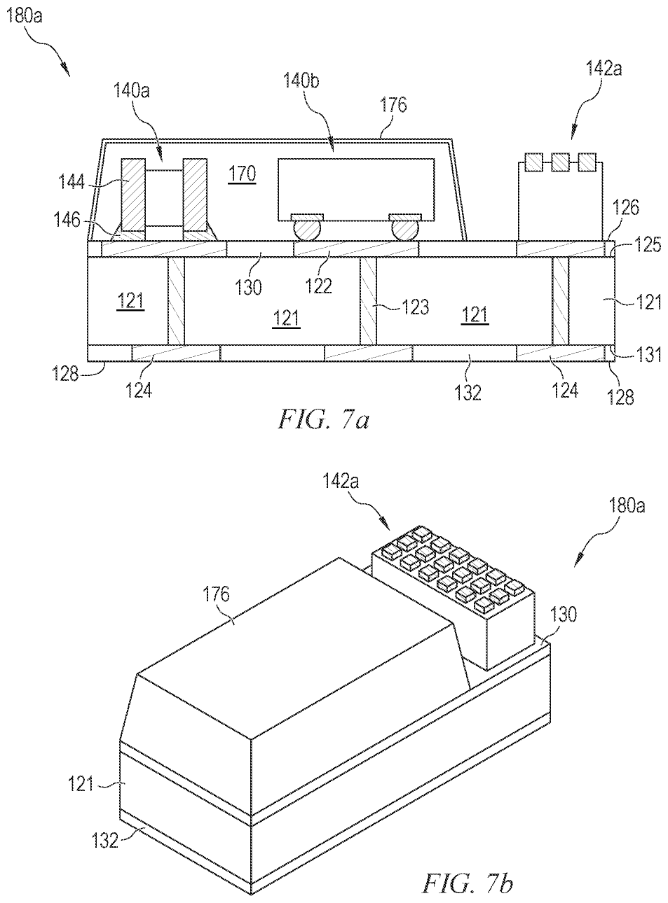

FIG. 7a illustrates AiP 180a post singulation. FIG. 7b is a perspective view of AiP 180a post singulation. Shielding material 176 over encapsulant 170 extends to the edge of AiP 180a. AiP 180b would have a similar view. Shielding material 176 can be formed over encapsulant 170 after singulation. AiP 180a is appliable to mobile electrical devices, such as 5G phones, as well as other portable multimedia devices.

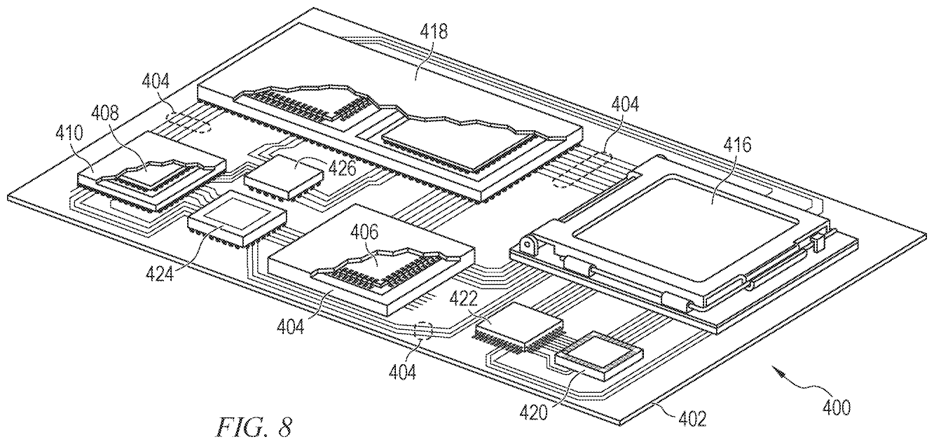

FIG. 8 illustrates electrical device 400 having a chip

carrier substrate or PCB 402 with a plurality of semiconductor packages disposed on a surface of PCB 402, including AiP 180a-180d. Electrical device 400 can have one type of semiconductor package, or multiple types of semiconductor packages, depending on the application.

Electrical device 400 can be a stand-alone system that

uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 8, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
a protective layer formed over a saw street of the substrate;
an electrical component disposed over a surface of the substrate; and
an encapsulant deposited over the electrical component, wherein the protective layer protects the substrate during encapsulation.

2. The semiconductor device of claim 1, further including a connector disposed over the surface of the substrate.

3. The semiconductor device of claim 1, wherein the protective layer extends over a width of the saw street.

4. The semiconductor device of claim 1, wherein the protective layer extends less than a width of the saw street.

5. The semiconductor device of claim 1, wherein the protective layer extends greater than a width of the saw street.

6. The semiconductor device of claim 1, further including a shielding layer formed over the encapsulant.

7. A semiconductor device, comprising:
a substrate;
a protective layer formed over a surface of the substrate;
an electrical component disposed over the surface of the substrate; and
an encapsulant deposited over the electrical component, wherein the protective layer protects the substrate during encapsulation.

8. The semiconductor device of claim 7, further including a connector disposed over the surface of the substrate.

9. The semiconductor device of claim 7, wherein the protective layer is formed over a saw street of the substrate.

10. The semiconductor device of claim 9, wherein the protective layer extends over a width of the saw street.

11. The semiconductor device of claim 9, wherein the protective layer extends less than a width of the saw street.

12. The semiconductor device of claim 9, wherein the protective layer extends greater than a width of the saw street.

13. The semiconductor device of claim 7, further including a shielding layer formed over the encapsulant.

14. A method of making a semiconductor device, comprising:
providing a substrate;
forming a protective layer over a saw street of the substrate;
disposing an electrical component over a surface of the substrate; and
depositing an encapsulant over the electrical component, wherein the protective layer protects the substrate during encapsulation.

15. The method of claim 14, further including disposing a connector over the surface of the substrate.

16. The method of claim 14, wherein the protective layer extends over a width of the saw street.

17. The method of claim 14, wherein the protective layer extends less than a width of the saw street.

18. The method of claim 14, wherein the protective layer extends greater than a width of the saw street.

19. The method of claim 14, further including forming a shielding layer over the encapsulant.

20. A method of making a semiconductor device, comprising:
providing a substrate;
forming a protective layer over a surface of the substrate;
disposing an electrical component over the surface of the substrate; and
depositing an encapsulant over the electrical component, wherein the protective layer protects the substrate during encapsulation.

21. The method of claim 20, further including disposing a connector over the surface of the substrate.

22. The method of claim 20, further including forming the protective layer over a saw street of the substrate.

23. The method of claim 22, wherein the protective layer extends over a width of the saw street.

24. The method of claim 22, wherein the protective layer extends less than a width of the saw street.

25. The method of claim 20, further including forming a shielding layer over the encapsulant.
